(19) United States
(12) Patent Application Publication
(10) Pub. No.: US 2021/0047219 A1
(43) Pub. Date: Feb. 18, 2021

(54) PROCESSING LIQUID CIRCULATING APPARATUS

(71) Applicant: DISCO CORPORATION, Tokyo (JP)

(72) Inventors: Jun SAITO, Tokyo (JP); Miki Vincent YOSHIDA, Tokyo (JP)

(21) Appl. No.: 16/990,177

(22) Filed: Aug. 11, 2020

(30) Foreign Application Priority Data
Aug. 16, 2019 (JP) 2019-149355

(51) Int. Cl. C02F 9/00; B01D 29/23

(52) U.S. Cl. CPC C02F 9/00; C02F 1/004; B01D 29/23

(57) ABSTRACT

A processing liquid circulating apparatus includes an ultraviolet radiation applying unit and a cleaning unit for cleaning a water flow passageway from a waste liquid tank to a clear water pump. The ultraviolet radiation applying unit includes an ultraviolet lamp, a quartz glass tube defining therein a first space surrounding the ultraviolet lamp, such that gas can be introduced into and discharged from the first space, and a frame defining therein a second space surrounding the quartz glass tube, such that clear water can be introduced into and discharged from the second space. The cleaning unit has an oxygen charge unit for charging oxygen into the first space, a first pipe interconnecting the second space and the clear water tank, and a second pipe interconnecting the ultraviolet radiation applying unit and the waste liquid tank.

### BACKGROUND OF THE INVENTION

### Field of the Invention

The present invention relates to a processing liquid circulating apparatus for supplying a processing liquid such as pure water to a processing apparatus.

### Description of the Related Art

For example, a processing liquid circulating apparatus disclosed in JP 2009-190128A or JP 2008-037695A produces clear water free of swarf by storing in a tank a processing waste liquid containing swarf delivered from a processing apparatus and passing the processing waste liquid pumped from the tank by a pump through a filter to remove the swarf from the processing waste liquid. The processing liquid circulating apparatus then applies an ultraviolet radiation to the produced clear water to turn organic substances in the clear water into ions, and passes the clear water through an ion exchange resin to cause the ion exchange resin to adsorb organic substance ions and inorganic substance ions, thereby reproducing the clear water as pure water. The pure water is delivered to the processing apparatus.

### SUMMARY OF THE INVENTION

The clear water free of the swarf contains organic substances immediately before the clear water flows from the tank to an ultraviolet radiation applying unit that applies an ultraviolet radiation to the clear water. When the processing liquid circulating apparatus is not operating, therefore, saprophytic bacteria tend to grow due to the organic substances contained in the clear water. If the processing liquid circulating apparatus shuts down for a long period of time, saprophytic bacteria are likely to multiply to the extent that they cannot be eliminated by the application of an ultraviolet radiation, and hence, the clear water is not sufficiently sterilized. Once saprophytic bacteria have been reproduced in the water in the tank, it is necessary to discard the water in the tank and pure water has to be produced by refining city water. Since it is time-consuming to produce pure water by refining city water, a problem arises in that the processing apparatus needs to be left on standby during the refinement of city water. In addition, there have been needs in the art for the reusing of clear water from which swarf has been removed to produce pure water.

It is therefore an object of the present invention to provide a processing liquid circulating apparatus that prevents saprophytic bacteria from being multiplied in a processing waste liquid and clear water that stay in tanks and pipes for interconnecting tanks and other components, etc., when the processing liquid circulating apparatus shuts down for a long period of time, i.e., when the processing liquid circulating apparatus does not deliver pure water to be supplied to a processing apparatus, for a long period of time.

In accordance with an aspect of the present invention, there is provided a processing liquid circulating apparatus including a waste liquid tank for storing a processing waste liquid containing swarf discharged from a processing apparatus that processes a workpiece, a waste liquid pump for pumping the processing waste liquid from the waste liquid tank, a filter unit for removing swarf from the processing waste liquid pumped from the waste liquid tank by the waste liquid pump, to thereby produce clear water, a clear water tank for storing clear water, a clear water pump for pumping clear water from the clear water tank, an ultraviolet radiation applying unit for applying an ultraviolet radiation to the clear water, an ion exchange resin unit for passing the clear water to which the ultraviolet radiation has been applied through an ion exchange resin, to produce pure water, and a cleaning unit for cleaning a water flow passageway from the waste liquid tank to the clear water pump. In the processing liquid circulating apparatus, the ultraviolet radiation applying unit has an ultraviolet lamp, a quartz glass tube defining therein a first space surrounding the ultraviolet lamp, a frame defining therein a second space surrounding the quartz glass tube, a gas inlet for introducing gas into the first space, a gas outlet for discharging the gas from the first space, a water inlet for introducing clear water into the second space, and a water outlet for discharging the clear water from the second space, the cleaning unit has an oxygen charge unit for introducing gas containing oxygen into the first space, a first pipe interconnecting the gas outlet and the clear water tank, and a second pipe interconnecting the water outlet and the waste liquid tank, and the gas containing oxygen that has been introduced into the first space is irradiated with the ultraviolet radiation, generating ozone, the gas containing the ozone is mixed with the clear water in the clear water tank, producing ozone water, and the ozone water is then introduced into the waste liquid tank and circulated successively through the waste liquid pump, the filter unit, the clear water tank, the clear water pump, the ultraviolet radiation applying unit, the second pipe, and the waste liquid tank, thereby cleaning the waste liquid tank, the waste liquid pump, the filter unit, the clear water tank, the clear water pump, the ultraviolet radiation applying unit, the second pipe, and the waste liquid tank.

According to the aspect of the present invention, the filter unit may have a filter that is of a tubular shape having a charge port defined centrally therein for charging the processing waste liquid therethrough into the filter and discharges clear water from openings defined in side walls, a tray on which the filter is placed, and a filter housing that houses the filter and the tray therein, and the cleaning unit may further include a gas charge unit for drawing gas in the filter housing and introducing the gas into the first space, drawing gas in the waste liquid tank and charging the gas into the first space, and drawing gas in the clear water tank and charging the gas into the first space.

According to the aspect of the present invention, the processing liquid circulating apparatus may further include an inactive gas charge unit for charging an inactive gas into the first space, and when clear water is delivered from the ultraviolet radiation applying unit to the ion exchange resin unit, the inactive gas charge unit may fill the first space with the inactive gas.

According to the aspect of the present invention, when the processing liquid circulating apparatus shuts down for a long period of time, i.e., when the processing liquid circulating apparatus does not deliver pure water to be supplied to a processing apparatus, for a long period of time, it is possible to prevent saprophytic bacteria from being multiplied in the waste liquid pump, the filter unit, the clear water tank, the clear water pump, the ultraviolet radiation applying unit, the second pipe, and the waste liquid tank. When the processing liquid circulating apparatus is to deliver pure water again to the processing apparatus, clear water in the processing liquid circulating apparatus can be reused without being discharged.

In a case where the filter unit has a filter that is of a tubular shape having a charge port defined centrally therein for charging the processing waste liquid therethrough into the filter and discharges clear water from openings defined in side walls, a tray on which the filter is placed, and a filter housing that houses the filter and the tray therein and the cleaning unit further includes a gas charge unit for drawing gas in the filter housing and introducing the gas into the first space, drawing gas in the waste liquid tank and charging the gas into the first space, and drawing gas in the clear water tank and charging the gas into the first space, when the ozone water containing the ozone generated in the first space is circulated through the waste liquid tank, the filter unit, and the clear water tank, ozone vaporized in the various components is retrieved back into the first space and is hence prevented from leaking out of the processing liquid circulating apparatus. The operator is thus free of the danger of inhaling ozone in the processing liquid circulating apparatus.

In a case where the processing liquid circulating apparatus further includes an inactive gas charge unit for charging an inactive gas into the first space, when clear water is delivered from the ultraviolet radiation applying unit to the ion exchange resin unit, e.g., when the processing liquid circulating apparatus is to deliver pure water again to the processing apparatus after not having delivered pure water to the processing apparatus for a long period of time, the inactive gas charge unit fills the first space with the inactive gas. The ultraviolet radiation emitted by the ultraviolet lamp is transmitted through the quartz glass tube without being attenuated in the first space and is applied to clear water in the second space. The ultraviolet radiation that has not been attenuated sufficiently sterilizes the clear water in the second space and also decomposes organic substances to generate pure water, thereby delivering pure water of high purity to the processing apparatus.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a schematic perspective view illustrating by way of example the structure of a processing liquid circulating apparatus according to an embodiment of the present invention;

FIG. 2 is a view illustrating by way of example the structure of an ultraviolet radiation applying unit and the manner in which the ultraviolet radiation applying unit, a cleaning unit, an inactive gas charge unit, a clear water tank, a clear water pump, and a waste liquid tank are held in fluid communication with each other while ozone water is being circulated; and

FIG. 3 is a view illustrating the manner in which clear water is delivered from the ultraviolet radiation applying unit to an ion exchange resin.

### DETAILED DESCRIPTION OF THE PREFERRED EMBODIMENT

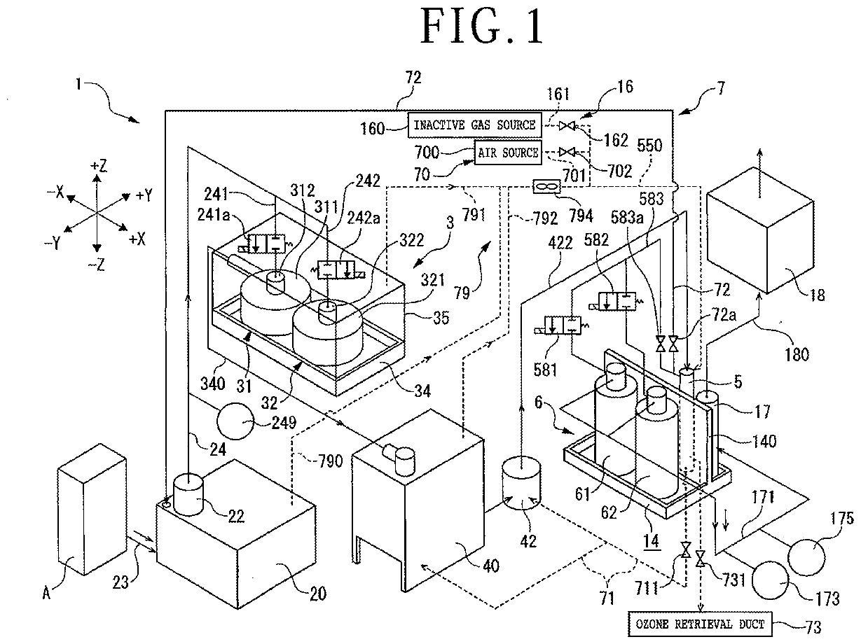

A processing apparatus A illustrated in FIG. 1 is, for example, either a grinding apparatus, used in a process of fabricating semiconductor devices, for grinding a workpiece such as a silicon wafer, for example, with a rotating grinding stone while supplying a processing liquid, i.e., pure water, to the workpiece, to thin the workpiece, or a cutting apparatus, used in a process of fabricating semiconductor devices, for cutting a workpiece held on a chuck table by causing a cutting blade that is rotating with respect to the workpiece to cut into the workpiece while supplying a processing liquid.

A processing liquid circulating apparatus 1 according to a preferred embodiment of the present invention is connected to the processing apparatus A. The processing liquid circulating apparatus 1 includes at least a waste liquid tank 20 for storing a processing waste liquid containing swarf discharged from the processing apparatus A that processes a workpiece while supplying a processing liquid thereto, a waste liquid pump 22 for pumping the processing waste liquid from the waste liquid tank 20, a filter unit 3 for removing swarf from the processing waste liquid pumped from the waste liquid tank 20 by the waste liquid pump 22, to thereby produce clear water, a clear water tank 40 for storing the clear water from the filter unit 3, a clear water pump 42 for pumping the clear water from the clear water tank 40, an ultraviolet radiation applying unit 5 for applying an ultraviolet radiation to the clear water, an ion exchange resin unit 6 for passing the clear water to which an ultraviolet radiation has been applied, through an ion exchange resin, to produce pure water, and a cleaning unit 7 for cleaning a water flow passageway from the waste liquid tank 20 to the clear water pump 42.

The processing waste liquid containing swarf, e.g., silicon swarf, discharged from the processing apparatus A passes through a processing waste liquid pipe 23 that may be in the form of a metal tube, a flexible tube, or the like and flows into the waste liquid tank 20.

The waste liquid pump 22 that is connected to the waste liquid tank 20 pumps the processing waste liquid from the waste liquid tank 20 under a negative pressure produced by the waste liquid pump 22 and delivers the processing waste liquid into a filter unit inlet pipe 24 whose one end is connected to the waste liquid pump 22.

The other end of the filter unit inlet pipe 24 is held in fluid communication with the filter unit 3. A pressure gage 249 is connected to the filter unit inlet pipe 24 for monitoring whether the rate at which the processing waste liquid delivered by the waste liquid pump 22 exceeds the processing capacity of the filter unit 3 is reached.

According to the present embodiment, the filter unit 3 that removes swarf from the processing waste liquid pumped from the waste liquid tank 20 by the waste liquid pump 22, to thereby produce clear water is a unit incorporating the product name “CC Filter” manufactured by DISCO Corporation, for example. The filter unit 3 includes a first filter 31 and a second filter 32, for example, as illustrated in FIG. 1. The processing waste liquid flowing through the filter unit inlet pipe 24 is introduced into the first filter 31 and the second filter 32.

The first filter 31 and the second filter 32, each in a tubular form, include respective tubular bodies 311 and 321 having a plurality of unillustrated openings defined in side walls thereof, respective charge ports 312 and 322 defined centrally in respective upper surfaces of the tubular bodies 311 and 321 for introducing the processing waste liquid therethrough into the tubular bodies 311 and 321, and respective unillustrated tubular filter papers disposed in the tubular bodies 311 and 321, respectively. In the first and second filters 31 and 32, the processing waste liquid introduced from the charge ports 312 and 322 into tubular filter papers is filtered by the tubular filter papers and discharged as clear water from the tubular bodies 311 and 321 through the openings defined in the side walls thereof.

The first filter 31 and the second filter 32 thus constructed are arrayed on a tub-like tray 34. Clear water from which swarf has been removed by the first and second filters 31 and 32 is discharged therefrom into the tray 34. A pipe 340 has an upstream end connected to the tray 34 and a downstream end connected to the clear water tank 40.

The first and second filters 31 and 32 and the tray 34 are housed in a box-shaped filter housing 35. The filter housing 35 is able to hold gas therein.

As illustrated in FIG. 1, the other end of the filter unit inlet pipe 24 is branched into a first filter unit inlet pipe 241 and a second filter unit inlet pipe 242. The first filter unit inlet pipe 241 is connected to the charge port 312 of the first filter 31, whereas the second filter unit inlet pipe 242 is connected to the charge port 322 of the second filter 32.

A first solenoid valve 241a is connected to the first filter unit inlet pipe 241, and a second solenoid valve 242a is connected to the second filter unit inlet pipe 242. The first solenoid valve 241a and the second solenoid valve 242a operate to selectively connect the first filter unit inlet pipe 241 and the second filter unit inlet pipe 242 to the first filter 31 and the second filter 32, respectively, or disconnect the first filter unit inlet pipe 241 and the second filter unit inlet pipe 242 from the first filter 31 and the second filter 32, respectively.

If only the first filter 31 continues to process the processing waste liquid, for example, swarf is deposited on the inside of the unillustrated filter paper of the first filter 31, tending to prevent the processing waste liquid from passing through the filter paper and hence to cause the first filter 31 to malfunction. As a result, the pressure gage 49 that measures the pressure in the filter unit inlet pipe 24 detects that the pressure has exceeded an allowable value. On the basis of a signal from the pressure gage 49, the first solenoid valve 241a is controlled to close itself to disconnect the first filter unit inlet pipe 241 from the first filter 31. Furthermore, the second solenoid valve 242a is controlled to open itself to connect the second filter unit inlet pipe 242 to the second filter 32. At the time the pressure gage 49 detects the pressure in the filter unit inlet pipe 24 has increased and has exceeded the allowable value, unillustrated alarm means is activated to issue an alarm and display on a screen a message indicating to the operator that the first filter 31 has malfunctioned and needs to be replaced.

As a consequence, the processing waste liquid delivered by the waste liquid pump 22 flows into the second filter 32, which processes the processing waste liquid in the same manner as the first filter 31. Since the first filter 31 has its filter paper ready to be replaced, the operator can replace the filter paper of the first filter 31. Consequently, even when the first filter 31 is being replaced, the processing liquid circulating apparatus 1 does not need to shut down as the second filter 32 is able to continuously process the processing waste liquid.

The clear water from the tray 34 flows through the pipe 340 into the clear water tank 40. The clear water stored in the clear water tank 40 is pumped therefrom by the clear water pump 42 illustrated in FIG. 1 and flows through an ultraviolet radiation applying unit inlet pipe 422 whose one end is connected to the clear water pump 42 into the ultraviolet radiation applying unit 5.

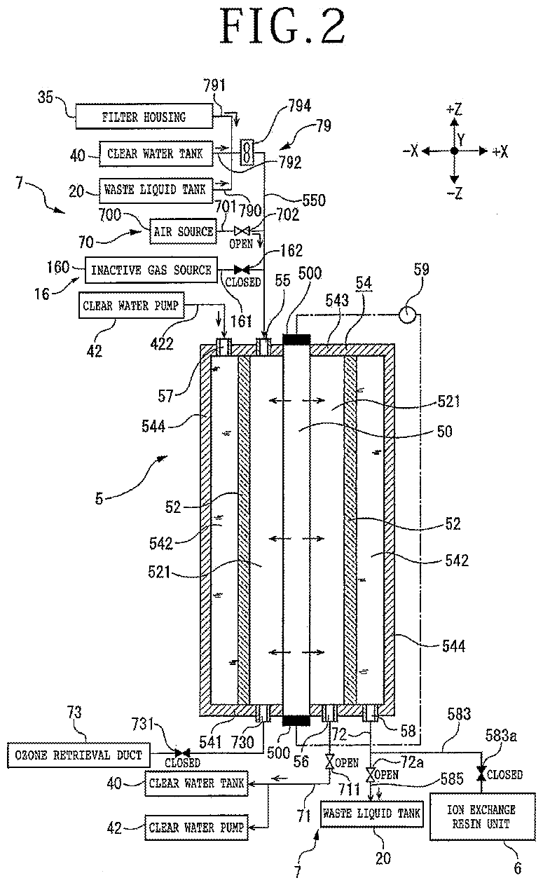

FIG. 2 illustrates the structure of the ultraviolet radiation applying unit 5 in vertical cross section. As illustrated in FIG. 2, the ultraviolet radiation applying unit 5 includes an ultraviolet lamp 50, a quartz glass tube 52 defining therein a first space 521 surrounding the ultraviolet lamp 50, a frame 54 defining therein a second space 542 surrounding the quartz glass tube 52, a gas inlet 55 for introducing gas into the first space 521, a gas outlet 56 for discharging the gas from the first space 521, a water inlet 57 for introducing clear water into the second space 542, and a water outlet 58 for discharging the clear water from the second space 542.

The ultraviolet lamp 50 is, for example, a low-pressure mercury lamp that efficiently radiates ultraviolet radiations laterally at respective short wavelengths of approximately 185 nm and approximately 254 nm as main wavelengths. However, the ultraviolet lamp 50 is not limited to such details. The ultraviolet lamp 50 is, for example, of a columnar shape extending vertically in Z-axis directions and has connection terminals 500 disposed respectively on upper and lower ends thereof and connected to a power supply 59.

The frame 54 is made of stainless steel of SUS or the like and is of a cylindrical shape. The frame 54 includes a bottom plate 541, a top plate 543 axially spaced from and facing the bottom plate 541, and a side wall 544 interconnecting the top plate 543 and the bottom plate 541.

The quartz glass tube 52 is made of quartz glass that is much purer than general glass and is able to transmit ultraviolet radiations well therethrough. The quartz glass tube 52 is, for example, of a hollow cylindrical shape and has upper and lower ends fixed to the top plate 543 and the bottom plate 541, respectively, of the frame 54. In the example illustrated in FIG. 2, the gas inlet 55 for introducing gas into the first space 521 is defined thicknesswise through the top plate 543, and the gas outlet 56 for discharging the gas from the first space 521 is defined thicknesswise through the bottom plate 541.

In the example illustrated in FIG. 2, the water inlet 57 for introducing clear water into the second space 542 is defined thicknesswise through the top plate 543. The other end of the ultraviolet radiation applying unit inlet pipe 422 is connected to the water inlet 57.

The water outlet 58 for discharging the clear water from the second space 542 is defined thicknesswise through the bottom plate 541.

The cleaning unit 7 for cleaning the water flow passageway from the waste liquid tank 20 to the clear water pump 42 illustrated in FIGS. 1 and 2 includes at least an oxygen charge unit 70 for introducing gas containing oxygen, i.e., air, into the first space 521, a first pipe 71 interconnecting the gas outlet 56 and the clear water tank 40, and a second pipe 72 interconnecting the water outlet 58 of the ultraviolet radiation applying unit 5 and the waste liquid tank 20. The cleaning unit 7 according to the present embodiment further includes a gas charge unit 79 for drawing gas in the filter housing 35 of the filter unit 3 and introducing the gas into the first space 521, drawing gas in the waste liquid tank 20 and introducing the gas into the first space 521, and drawing gas in the clear water tank 40 and introducing the gas into the first space 521.

As illustrated in FIG. 2, a main pipe 550 is connected to the gas inlet 55 that introduces gas into the first space 521 in the ultraviolet radiation applying unit 5.

The oxygen charge unit 70 includes an air source, i.e., an oxygen source, 700 such as a compressor or a blower, for example, an air charge pipe 701 interconnecting the main pipe 550 and the air source 700, and an air source on/off valve 702 connected to the air charge pipe 701.

The gas charge unit 79 illustrated in FIGS. 1 and 2 includes a waste liquid tank gas drawing pipe 790 having an end connected to the waste liquid tank 20, a housing gas drawing pipe 791 having an end connected to the filter housing 35 of the filter unit 3, and a clear water tank gas drawing pipe 792 having an end connected to the clear water tank 40. The other end of the waste liquid tank gas drawing pipe 790, the other end of the housing gas drawing pipe 791, and the other end of the clear water tank gas drawing pipe 792 are connected to the main pipe 550 connected to the gas inlet 55 through a suction fan 794.

According to the present embodiment, the first pipe 71 that interconnects the gas outlet 56 and the clear water tank 40 is also connected to the clear water pump 42, as illustrated in FIGS. 1 and 2. A first pipe on/off valve 711 is connected to the first pipe 71.

The second pipe 72 branches into an ion exchange inlet pipe 583 connected to the ion exchange resin unit 6. An inlet pipe on/off valve 583a is connected to the ion exchange inlet pipe 583, and a second pipe on/off valve 72a is connected to the second pipe 72.

The processing liquid circulating apparatus 1 according to the present embodiment includes an inactive gas charge unit 16 for introducing an inactive gas into the first space 521 in the ultraviolet radiation applying unit 5 illustrated in FIG. 2. The inactive gas charge unit 16 includes an inactive gas source 160 for storing a nitrogen gas, for example, a gas charge pipe 161 interconnecting the main pipe 550 and the inactive gas source 160, and a gas source on/off valve 162 connected to the gas charge pipe 161. The inactive gas source 160 stores an argon gas instead of the nitrogen gas.

As illustrated in FIG. 1, the ultraviolet radiation applying unit 5 is detachably disposed on a support base 14 illustrated in FIG. 1, for example. A partition plate 140 is erected on the support base 14 so as to extend in the Z-axis directions. The ultraviolet radiation applying unit 5 is positioned behind the partition plate 140 on the support base 14, i.e., rearwardly of the partition plate 140 in a +Y direction that is one of Y-axis directions. A precision filter 17 is detachably mounted on the support base 14 rearwardly of the partition plate 140 in the +Y direction, adjacent to the ultraviolet radiation applying unit 5.

According to the present embodiment, the ion exchange resin unit 6 illustrated in FIG. 1 includes a first ion exchanger 61 and a second ion exchanger 62, for example. The first ion exchanger 61 and the second ion exchanger 62 are detachably disposed forwardly of the partition plate 140 in a −Y direction that is the other of the Y-axis directions and are arrayed on the support base 14.

The clear water supplied to the ultraviolet radiation applying unit 5 is sterilized, and organic substances contained therein are ionized by the ultraviolet radiation applied by the ultraviolet radiation applying unit 5. The clear water thus processed is discharged from the second space 542 (see FIG. 2) through the water outlet 58, then flows through the ion exchange inlet pipe 583, and is branched so as to be introduced into the first ion exchanger 61 and the second ion exchanger 62.

The ion exchange inlet pipe 583 is branched downstream of the inlet pipe on/off valve 583a into two branch pipes to which a first solenoid-operated on/off valve 581 and a second solenoid-operated on/off valve 582 are connected, respectively. When the first solenoid-operated on/off valve 581 is opened, the clear water sterilized by the ultraviolet radiation is introduced therethrough into the first ion exchanger 61. When the second solenoid-operated on/off valve 582 is opened, the clear water sterilized by the ultraviolet radiation is introduced therethrough into the second ion exchanger 62. The clear water introduced into the first ion exchanger 61 or the second ion exchanger 62 is refined into pure water by way of an ion exchange. When the first ion exchanger 61 is to be replaced, for example, the first solenoid-operated on/off valve 581 is closed, and the clear water is temporarily introduced into only the second ion exchanger 62.

The pure water thus produced from the clear water by way of an ion exchange may contain fine particles such as of resin debris of the ion exchange resin of the first and second ion exchangers 61 and 62. For this reason, the pure water produced from the clear water by way of an ion exchange by the first and second ion exchangers 61 and 62 is introduced through a pipe 171 into the precision filter 17, which traps fine particles such as of resin debris of the ion exchange resin that may be contained in the pure water.

As illustrated in FIG. 1, a pressure gage 173 for measuring the pressure of pure water delivered from the first and second ion exchangers 61 and 62 to the precision filter 17 is connected to the pipe 171. When the pressure in the pipe 171 that is measured by the pressure gage 173 has reached a predetermined pressure value or higher, the pressure gage 173 decides that the precision filter 17 has malfunctioned due to a deposit of fine particles such as of resin debris in the precision filter 17, and issues an alarm and displays on a screen a message indicating to the operator that the precision filter 17 needs to be replaced.

Moreover, a specific resistance meter 175 for detecting the specific resistance of pure water delivered from the first ion exchanger 61 or the second ion exchanger 62 to the precision filter 17 may be connected to the pipe 171.

Pure water that has passed through the precision filter 17 is delivered through a pipe 180 to a pure water temperature regulator 18. The pure water delivered to the pure water temperature regulator 18 is regulated to a predetermined temperature and is then supplied to an unillustrated processing liquid supply unit in the processing apparatus A illustrated in FIG. 1.

Operation of the various components of the processing liquid circulating apparatus 1 for preventing saprophytic bacteria from being multiplied in the processing waste liquid and the clear water that stay in the waste liquid tank 20, the waste liquid pump 22, the filter unit 3, the clear water tank 40, the clear water pump 42, the ultraviolet radiation applying unit 5, and the various pipes interconnecting those components when the processing liquid circulating apparatus 1 shuts down for a long period of time, i.e., when the processing liquid circulating apparatus 1 does not deliver pure water to be supplied to the processing apparatus A, for a long period of time, will be explained.

First, as illustrated in FIG. 2, with the air source on/off valve 702 being open, the air source 700 supplies a predetermined amount of air, i.e., oxygen, to the air charge pipe 701. The air flows from the air charge pipe 701 into the main pipe 550 and then flows from the main pipe 550 through the gas inlet 55 into the first space 521 in the ultraviolet radiation applying unit 5.

The ultraviolet lamp 50 is energized by the power supply 59, simultaneously applying ultraviolet radiations at respective wavelengths of approximately 185 nm and approximately 254 nm to the air, i.e., gas, containing oxygen introduced into the first space 521. As a result, oxygen molecules contained in the air in the first space 521 absorb the ultraviolet radiation having the wavelength of approximately 185 nm and are decomposed into oxygen atoms. In other words, the ultraviolet radiation is attenuated by the air containing oxygen. The generated oxygen atoms are combined with oxygen molecules therearound, generating ozone. Therefore, the air in the first space 521 takes on sterilizing power based on the generated ozone, i.e., active oxygen.

The ozone, i.e., gas, generated in the first space 521 is discharged from the gas outlet 56, flows through the first pipe 71 with the first pipe on/off valve 711 being open into the clear water tank 40 and/or the clear water pump 42. The introduced ozone is mixed and/or combined with clear water stored in the clear water tank 40 and/or the clear water pump 42, turning the clear water into ozone water.

The ozone water generated in the clear water tank 40 and/or the clear water pump 42 is pumped by the clear water pump 42 and delivered through the ultraviolet radiation applying unit inlet pipe 422 illustrated in FIG. 1 to the ultraviolet radiation applying unit 5. Then, the ozone water flows from the water inlet 57 of the ultraviolet radiation applying unit 5 illustrated in FIG. 2 into the second space 542.

The ozone water that has flowed into the second space 542 is discharged from the water outlet 58 and flows through the second pipe 72 with the second pipe on/off valve 72a being open into the waste liquid tank 20. The inlet pipe on/off valve 583a that is connected to the ion exchange inlet pipe 583 branched from the second pipe 72 has been closed, stopping the ozone water from flowing to the ion exchange resin unit 6.

A predetermined amount, e.g., approximately 60 liters, of processing waste liquid stored in the waste liquid tank 20 is now cleaned by the ozone water. In other words, saprophytic bacteria contained in the processing waste liquid in the waste liquid tank 20 are sterilized. Thereafter, the ozone water is pumped from the waste liquid tank 20 by the waste liquid pump 22, cleans the processing waste liquid in the waste liquid pump 22, and flows through the filter unit inlet pipe 24 while cleaning the inside thereof.

The ozone water flowing through the filter unit inlet pipe 24 flows into the first and second filters 31 and 32 of the filter unit 3 and passes through the first and second filters 31 and 32, removing swarf therefrom and flowing into the tray 34. Then, the ozone water flows out of the tray 34 into the pipe 340, from which the ozone water flows into the clear water tank 40. In this manner, the filter unit 3 is sterilized and cleaned by the ozone water.

Furthermore, the ozone water pumped from the clear water tank 40 by the clear water pump 42 flows through the water inlet 57 of the ultraviolet radiation applying unit 5 into the second space 542 therein, circulating through the same route as described above.

As described above, the processing liquid circulating apparatus 1 according to the present invention includes the ultraviolet radiation applying unit 5 and the cleaning unit 7 for cleaning the water flow passageway from the waste liquid tank 20 to the clear water pump 42. The ultraviolet radiation applying unit 5 has the ultraviolet lamp 50, the quartz glass tube 52 defining therein the first space 521 surrounding the ultraviolet lamp 50, the frame 54 defining therein the second space 542 surrounding the quartz glass tube 52, the gas inlet 55 for introducing gas into the first space 521, the gas outlet 56 for discharging the gas from the first space 521, the water inlet 57 for introducing clear water into the second space 542, and the water outlet 58 for discharging the clear water from the second space 542. The cleaning unit 7 has the oxygen charge unit 70 for introducing gas containing oxygen into the first space 521, the first pipe 71 interconnecting the gas outlet 56 and the clear water tank 40, and the second pipe 72 interconnecting the water outlet 58 and the waste liquid tank 20. The gas containing oxygen that has been introduced into the first space 521 is irradiated with the ultraviolet radiation, generating ozone. The gas containing the ozone is mixed with the clear water in the clear water tank 40, producing ozone water. The ozone water is then introduced into the waste liquid tank 20 and circulated successively through the waste liquid pump 22, the filter unit 3, the clear water tank 40, the clear water pump 42, the ultraviolet radiation applying unit 5, the second pipe 72, and the waste liquid tank 20, cleaning, i.e., sterilizing, the processing waste liquid and the clear water that are stored in those components. It is thus possible to prevent saprophytic bacteria from being multiplied in the waste liquid pump 22, the filter unit 3, the clear water tank 40, the clear water pump 42, the ultraviolet radiation applying unit 5, the second pipe 72, and the waste liquid tank 20 when the processing liquid circulating apparatus 1 shuts down for a long period of time, i.e., when the processing liquid circulating apparatus 1 does not deliver pure water to be supplied to the processing apparatus A, for a long period of time. Moreover, in a case where the processing liquid circulating apparatus 1 delivers pure water again to the processing apparatus A, clear water in the processing liquid circulating apparatus 1 can be reused without being discharged, i.e., discarded.

The cleaning unit 7 of the processing liquid circulating apparatus 1 according to the present embodiment includes the gas charge unit 79 illustrated in FIGS. 1 and 2. The gas charge unit 79 operates when ozone water starts being circulated in the processing liquid circulating apparatus 1.

When the ozone water is introduced into the waste liquid tank 20 illustrated in FIG. 1, some ozone is vaporized from the ozone water in the waste liquid tank 20 and stays in an upper portion of the space in the waste liquid tank 20. The suction fan 794 of the gas charge unit 79 is actuated to draw the ozone released from the ozone water in the waste liquid tank 20 through the waste liquid tank gas drawing pipe 790 and to charge the ozone through the main pipe 550 and the gas inlet 55 (see FIG. 2) into the first space 521 in the ultraviolet radiation applying unit 5.

When the ozone water is introduced into the clear water tank 40, some ozone is vaporized from the ozone water in the clear water tank 40 and stays in an upper portion of the space in the clear water tank 40. The suction fan 794 draws the ozone released from the ozone water in the clear water tank 40 through the clear water tank gas drawing pipe 792 and charges the ozone through the main pipe 550 and the gas inlet 55 into the first space 521 in the ultraviolet radiation applying unit 5.

When the ozone water is introduced into the first filter 31 or the second filter 32, some ozone is vaporized from the ozone water discharged from the first filter 31 or the second filter 32 into the tray 34 and stays in an upper portion of the space in the filter housing 35. The suction fan 794 draws the ozone released from the ozone water in the filter housing 35 through the housing gas drawing pipe 791 and charges the ozone through the main pipe 550 and the gas inlet 55 into the first space 521 in the ultraviolet radiation applying unit 5.

As described above, as the cleaning unit 7 of the processing liquid circulating apparatus 1 according to the present embodiment includes the gas charge unit 79, when the ozone water containing the ozone generated in the first space 521 is circulated through the waste liquid tank 20, the filter unit 3, and the clear water tank 40, ozone vaporized in the various components is retrieved back into the first space 521 and is hence prevented from leaking out of the processing liquid circulating apparatus 1. The operator is thus free of the danger of inhaling ozone in the processing liquid circulating apparatus 1.

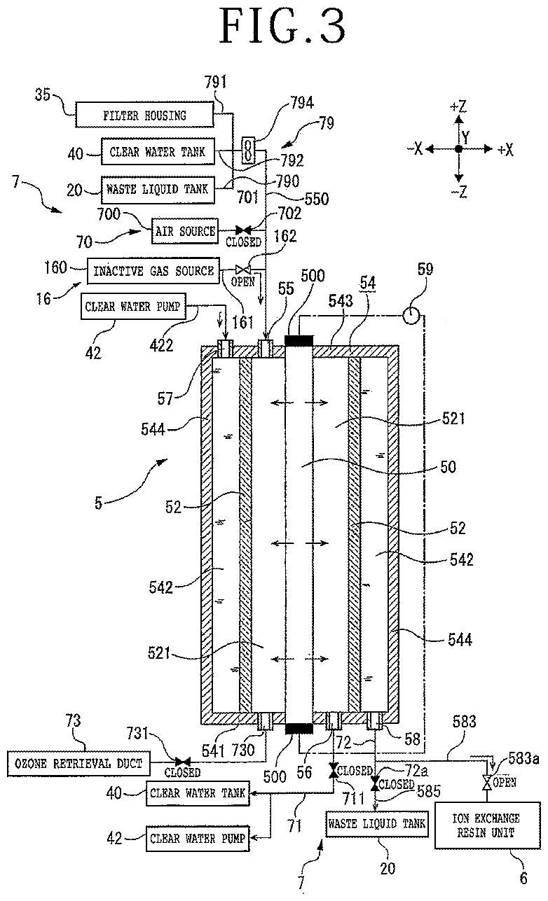

Operation of the processing liquid circulating apparatus 1 at the time clear water is to be delivered from the ultraviolet radiation applying unit 5 illustrated in FIGS. 1 and 3 to the ion exchange resin unit 6, i.e., at the time the processing liquid circulating apparatus 1 is to deliver pure water again to the processing apparatus A after not having delivered pure water to the processing apparatus A for a long period of time, will be explained.

First, as illustrated in FIG. 3, the air source on/off valve 702 of the oxygen charge unit 70 of the cleaning unit 7 is closed, stopping charging oxygen into the first space 521 in the ultraviolet radiation applying unit 5. The bottom plate 541 of the frame 54 has an ozone discharge hole 730 held in communication with an ozone retrieval duct 73 through an on/off valve 731. When the on/off valve 731 is opened, ozone remaining in the first space 521 is discharged therefrom through the ozone discharge hole 730. Alternatively, ozone remaining in the first space 521 may be allowed to be self-decomposed after oxygen has stopped being charged into the first space 521, instead of being discharged therefrom through the ozone discharge hole 730 into the ozone retrieval duct 73.

Then, the on/off valve 731 is closed, and an inactive gas, e.g., a nitrogen gas, is charged from the inactive gas source 160 of the inactive gas charge unit 16 through the gas source on/off valve 162 as it is open, the gas charge pipe 161, the main pipe 550, and the gas inlet 55 into the first space 521 in the ultraviolet radiation applying unit 5, filling up the first space 521 with the inactive gas. The first pipe on/off valve 711 is closed to prevent the inactive gas from flowing into the clear water tank 40.

The ultraviolet lamp 50 simultaneously applies ultraviolet radiations at respective wavelengths of approximately 185 nm and approximately 254 nm, which are transmitted through the quartz glass tube 52 without being attenuated by the inactive gas and reach the clear water in the second space 542. Saprophytic bacteria contained in the clear water are now sterilized, and organic substances in the clear water are decomposed, i.e., ionized.

Since no new ozone has been introduced into the clear water delivered from the clear water tank 40 illustrated in FIGS. 1 and 3 into the second space 542 in the ultraviolet radiation applying unit 5, any ozone remaining in the clear water has been self-decomposed and eliminated.

The clear water in the second space 542 is discharged through the water outlet 58 and flows through the ion exchange inlet pipe 583 with the inlet pipe on/off valve 583a being open into the ion exchange resin unit 6. The second pipe on/off valve 72a is closed to prevent the clear water from flowing into the waste liquid tank 20.

The clear water introduced into the ion exchange resin unit 6 is turned into pure water by way of an ion exchange by the ion exchange resin unit 6. The pure water flows through the precision filter 17, which traps fine particles such as of resin debris of the ion exchange resin that may be contained in the pure water. The pure water is delivered to the pure water temperature regulator 18, regulated to a predetermined temperature, and then supplied to the unillustrated processing liquid supply unit in the processing apparatus A illustrated in FIG. 1.

The processing liquid circulating apparatus 1 according to the present invention includes the inactive gas charge unit 16 for introducing an inactive gas into the first space 521 in the ultraviolet radiation applying unit 5. When the ultraviolet radiation applying unit 5 is to deliver clear water to the ion exchange resin unit 6, i.e., when the processing liquid circulating apparatus 1 is to deliver pure water again to the processing apparatus A after not having delivered pure water to the processing apparatus A for a long period of time, the inactive gas charge unit 16 fills the first space 521 with the inactive gas. As there is no oxygen in the first space 521, the energy of the ultraviolet radiation emitted by the ultraviolet lamp 50 is not attenuated in the first space 521, but is transmitted through the quartz glass tube 52 and applied to the clear water in the second space 542. The ultraviolet radiation that has not been attenuated sterilizes saprophytic bacteria contained in the clear water in the second space 542 and also decomposes organic substances and turns them into ions. The first ion exchanger 61 and the second ion exchanger 62 adsorb the organic substance ions, generating and delivering pure water of high purity to the processing apparatus A. Moreover, in a case where the processing liquid circulating apparatus 1 delivers pure water again to the processing apparatus A, clear water in the processing liquid circulating apparatus 1 can be reused without being discharged.

The processing liquid circulating apparatus 1 according to the present invention is not limited to the illustrated details according to the above embodiment. The present invention is not limited to the structural details illustrated in the accompanying drawings, and various changes and modifications may be made therein without departing from the scope of the invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing liquid circulating apparatus comprising:
a waste liquid tank for storing a processing waste liquid containing swarf discharged from a processing apparatus that processes a workpiece;
a waste liquid pump for pumping the processing waste liquid from the waste liquid tank;
a filter unit for removing swarf from the processing waste liquid pumped from the waste liquid tank by the waste liquid pump, to thereby produce clear water;
a clear water tank for storing clear water;
a clear water pump for pumping clear water from the clear water tank;
an ultraviolet radiation applying unit for applying an ultraviolet radiation to the clear water;
an ion exchange resin unit for passing the clear water to which the ultraviolet radiation has been applied through an ion exchange resin, to produce pure water; and
a cleaning unit for cleaning a water flow passageway from the waste liquid tank to the clear water pump,
wherein the ultraviolet radiation applying unit has an ultraviolet lamp, a quartz glass tube defining therein a first space surrounding the ultraviolet lamp, a frame defining a second space surrounding the quartz glass tube, a gas inlet for introducing gas into the first space, a gas outlet for discharging the gas from the first space, a water inlet for introducing clear water into the second space, and a water outlet for discharging the clear water from the second space,
the cleaning unit has an oxygen charge unit for introducing gas containing oxygen into the first space, a first pipe interconnecting the gas outlet and the clear water tank, and a second pipe interconnecting the water outlet and the waste liquid tank, and
the gas containing oxygen that has been introduced into the first space is irradiated with the ultraviolet radiation, generating ozone, the gas containing the ozone is mixed with the clear water in the clear water tank, producing ozone water, and the ozone water is then introduced into the waste liquid tank and circulated successively through the waste liquid pump, the filter unit, the clear water tank, the clear water pump, the ultraviolet radiation applying unit, the second pipe, and the waste liquid tank, thereby cleaning the waste liquid tank, the waste liquid pump, the filter unit, the clear water tank, the clear water pump, the ultraviolet radiation applying unit, the second pipe, and the waste liquid tank.

2. The processing liquid circulating apparatus according to claim 1,
wherein the filter unit has a filter that is of a tubular shape having a charge port defined centrally in the filter for charging the processing waste liquid into the filter and discharges clear water from openings defined in side walls, a tray on which the filter is placed, and a filter housing that houses the filter and the tray, and
the cleaning unit further includes a gas charge unit for drawing gas in the filter housing and introducing the gas into the first space, drawing gas in the waste liquid tank and charging the gas into the first space, and drawing gas in the clear water tank and charging the gas into the first space.

3. The processing liquid circulating apparatus according to claim 1, further comprising:
an inactive gas charge unit for charging an inactive gas into the first space,
wherein, when clear water is delivered from the ultraviolet radiation applying unit to the ion exchange resin unit, the inactive gas charge unit fills the first space with the inactive gas.

4. The processing liquid circulating apparatus according to claim 2, further comprising:
an inactive gas charge unit for charging an inactive gas into the first space,
wherein, when clear water is delivered from the ultraviolet radiation applying unit to the ion exchange resin unit, the inactive gas charge unit fills the first space with the inactive gas.
